(19) United States
(12) Patent Application Publication
(10) Pub. No.: US 2026/0128716 A1
(43) Pub. Date: May 7, 2026

(54) POWER AMPLIFIER WITH STACKED STRUCTURE AND COMMUNICATION CIRCUIT THEREOF

(71) Applicant: SAMSUNG ELECTRONICS CO., LTD., Suwon-si (KR)

(72) Inventors: Jooseok LEE, Suwon-si (KR); Dongsoo LEE, Suwon-si (KR); Daehoon KWON, Suwon-si (KR); Sunggi YANG, Suwon-si (KR)

(73) Assignee: SAMSUNG ELECTRONICS CO., LTD., Suwon-si (KR)

(21) Appl. No.: 19/370,206

(22) Filed: Oct. 27, 2025

Related U.S. Application Data
(63) Continuation of application No. PCT/KR2025/014882, filed on Sep. 23, 2025.

(30) Foreign Application Priority Data
Nov. 6, 2024 (KR) 10-2024-0156471

(51) Int. Cl. H03F 1/22; H03F 1/30; H03F 3/24

(52) U.S. Cl. CPC H03F 1/223; H03F 1/301; H03F 3/245; H03F 2200/451

(57) ABSTRACT

A power amplifier is provided. The power amplifier includes: an amplifier circuit including a first transistor, a second transistor, and a third transistor connected in a stacked cascode structure between a power supply voltage and a ground; and a bias circuit including a first operational amplifier configured to provide a first bias voltage to the first transistor, and a second operational amplifier configured to provide a second bias voltage to the second transistor. The first operational amplifier includes a positive input terminal connected to a first reference voltage divided from the power supply voltage, a negative input terminal connected to a source node of the first transistor, an output terminal configured to provide the first bias voltage to a gate node of the first transistor, a positive power supply terminal connected to the power supply voltage, and a negative power supply terminal.

### CROSS-REFERENCE TO RELATED APPLICATIONS

This application is a bypass continuation of International application No. PCT/KR2025/014882, filed on Sep. 23, 2025, which is based on and claims priority to Korean Patent Application No. 10-2024-0156471, filed on Nov. 6, 2024, in the Korean Intellectual Property Office, the disclosures of which are incorporated by reference herein in their entireties.

### BACKGROUND

### 1. Field

One or more embodiments relate to a power amplifier with a stacked structure and a communication circuit thereof.

### 2. Description of Related Art

To meet the growing demand for wireless data traffic following 4G systems (i.e., long-term evolution (LTE) systems), 5G systems are being developed and commercialized. 5G systems may be implemented in a millimeter wave (mmWave) band. To mitigate path loss of radio waves and increase the transmission distance of radio waves in the mmWave band, ongoing research is being performed with respect to beamforming, massive multiple-input multiple-output (MIMO), full dimensional MIMO (FD-MIMO), array antenna, analog beamforming, and large-scale antenna.

In a MIMO-based 5G system using the mmWave band, a base station may form single beam or multiple beams through array antennas and use the beams for communication with a user equipment (UE). The base station may improve communication quality by concentrating signals in the direction of each of one or more UEs through beamforming.

With the advancement of technologies such as the internet of things (IoT), cloud computing, and big data, and the increase in public data consumption, the demand for large-capacity wireless communication technology is rapidly increasing. Frequency bands are becoming saturated with various communication services and have limited bandwidths, making it difficult to provide higher data transmission rates. Therefore, signal processing in higher frequency bands is required to implement large-capacity wireless communication technology.

A high frequency band, for example, the mmWave band above 10 GHz, may significantly increase data transmission rates based on a wide bandwidth and avoid congestion in a low frequency band, thereby enabling high-quality communication services to be provided. However, the mmWave band suffers from large propagation loss and is easily blocked by obstacles.

In order to overcome the above problems, research on beamforming, increasing a cell density, and high-power power amplifiers is being conducted. A high-power power amplifier amplifies the strength of an output signal to increase a communication distance and provide a stable connection. A complementary metal-oxide-semiconductor (CMOS) field-effect transistor (MOSFET)-based power amplifier is inexpensive and has a very high integration level, which may facilitate implementation of beamforming technology at a high frequency. However, compared to other compound semiconductors (e.g., gallium arsenide (GaAs) or gallium nitride (GaN)), low power may be available for the CMOS-based power amplifier and it may be difficult to provide high output power with the CMOS-based power amplifier.

The above information is presented as background information only to assist with an understanding of the present disclosure. No determination has been made, and no assertion is made, as to whether any of the above might be applicable as prior art with regard to the present disclosure.

### SUMMARY

One or more embodiments provide a power amplifier with a stacked structure and a communication circuit thereof.

One or more embodiments also provide a communication circuit including a bias circuit for a stacked cascade power amplifier.

The technical problems to be solved by the disclosure is not limited to the technical problems mentioned above, and other technical problems not mentioned will be clearly understood by those skilled in the art to which the disclosure pertains from the following description.

According to embodiments of the disclosure, a power amplifier may include: an amplifier circuit including a first transistor, a second transistor, and a third transistor connected in a stacked cascode structure between a power supply voltage and a ground; and a bias circuit including a first operational amplifier configured to provide a first bias voltage to the first transistor, and a second operational amplifier configured to provide a second bias voltage to the second transistor. The first operational amplifier may include a positive input terminal connected to a first reference voltage divided from the power supply voltage, a negative input terminal connected to a source node of the first transistor, an output terminal configured to provide the first bias voltage to a gate node of the first transistor, a positive power supply terminal connected to the power supply voltage, and a negative power supply terminal. The second operational amplifier may include a positive input terminal connected to a second reference voltage divided from the power supply voltage, a negative input terminal connected to a source node of the second transistor, an output terminal configured to provide the second bias voltage to a gate node of the second transistor, a positive power supply terminal connected to the negative power supply terminal of the first operational amplifier, and a negative power supply terminal connected to the ground.

The power amplifier may further include a resistor ladder with a first resistor, a second resistor, and a third resistor connected in series between the power supply voltage and the ground. The positive input terminal of the first operational amplifier may be connected to the resistor ladder between the first resistor and the second resistor, and the positive input terminal of the second operational amplifier may be connected to the resistor ladder between the second resistor and the third resistor.

At least one of the first resistor, the second resistor, or the third resistor may be a variable resistor.

An input radio frequency (RF) signal may be received through a gate node of the third transistor. An amplified output RF signal corresponding to the input RF signal may be output through a drain node of the first transistor.

The power amplifier may further include an inductor coil connected between the power supply voltage and the drain node of the first transistor.

The amplifier circuit may further include a fourth transistor connected to the first transistor in a stacked cascode structure, and the bias circuit may further include a third operational amplifier configured to provide a bias voltage to the fourth transistor.

The power amplifier may further include a voltage regulator configured to generate source voltages to be provided to the first operational amplifier and the second operational amplifier, based on the power supply voltage.

The power amplifier may further include an analog bias circuit including a mirror transistor corresponding to the third transistor and a third operational amplifier configured to provide a third bias voltage to the mirror transistor. The third operational amplifier may include a positive input terminal connected to an analog power supply voltage, a negative input terminal connected to the positive input terminal of the second operational amplifier, a positive power supply terminal connected to the analog power supply voltage, and a negative power supply terminal connected to the ground. The mirror transistor may include a gate node connected to the gate node of the third transistor, a drain node connected to the analog power supply voltage via a reference current source, and a source node connected to the ground.

The first transistor, the second transistor, and the third transistor may be complementary metal-oxide-semiconductor (MOS) (CMOS) transistors.

The amplifier circuit may be configured to be used in a transmission path of an RF communication circuit configured to support a millimeter wave (mmWave) frequency band.

According to embodiments of the disclosure, a communication circuit may include a transmission path, wherein the transmission path may include one or more power amplifiers, and among the one or more power amplifiers, at least one power amplifier may include: an amplifier circuit including a first transistor, a second transistor, and a third transistor connected in a stacked cascode structure between a power supply voltage and a ground; and a bias circuit including a first operational amplifier configured to provide a first bias voltage to the first transistor, and a second operational amplifier configured to provide a second bias voltage the second transistor. The first operational amplifier may include a positive input terminal connected to a first reference voltage divided from the power supply voltage, a negative input terminal connected to a source node of the first transistor, an output terminal configured to provide the first bias voltage to a gate node of the first transistor, a positive power supply terminal connected to the power supply voltage, and a negative power supply terminal. The second operational amplifier may include a positive input terminal connected to a second reference voltage divided from the power supply voltage, a negative input terminal connected to a source node of the second transistor, an output terminal configured to provide the second bias voltage to a gate node of the second transistor, a positive power supply terminal connected to the negative power supply terminal of the first operational amplifier, and a negative power supply terminal connected to the ground.

The at least one power amplifier may further include a resistor ladder including a first resistor, a second resistor, and a third resistor connected in series between the power supply voltage and the ground. The positive input terminal of the first operational amplifier may be connected to the resistor ladder between the first resistor and the second resistor, and the positive input terminal of the second operational may be is connected to the resistor ladder between the second resistor and the third resistor.

At least one of the first resistor, the second resistor, or the third resistor may be a variable resistor.

An input RF signal may be received through a gate node of the third transistor, and an amplified output RF signal corresponding to the input RF signal may be output through a drain node of the first transistor.

The at least one power amplifier may further include an inductor coil connected between the power supply voltage and the drain node of the first transistor.

The amplifier circuit may further comprise a fourth transistor connected to the first transistor in a stacked cascode structure, and the bias circuit may further comprise a third operational amplifier configured to provide a bias voltage to the fourth transistor.

The amplifier circuit may further comprise a voltage regulator configured to generate source voltages to be provided to the first operational amplifier and the second operational amplifier, based on the power supply voltage.

The amplifier circuit may further comprise an analog bias circuit including a mirror transistor corresponding to the third transistor and a third operational amplifier configured to provide a third bias voltage to the mirror transistor. The third operational amplifier may comprise a positive input terminal connected to an analog power supply voltage, a negative input terminal connected to the positive input terminal of the second operational amplifier, a positive power supply terminal connected to the analog power supply voltage, and a negative power supply terminal connected to the ground. The mirror transistor may comprise a gate node connected to the gate node of the third transistor, a drain node connected to the analog power supply voltage via a reference current source, and a source node connected to the ground.

The first transistor, the second transistor, and the third transistor may be CMOS transistors.

The transmission path may be configured to support an mmWave frequency band.

### BRIEF DESCRIPTION OF DRAWINGS

The above and other aspects, features and advantages of certain embodiments of the present disclosure will be more apparent from the following description taken in conjunction with the accompanying drawings, in which:

FIG. 1 is a block diagram illustrating an electronic device in a network environment according to various embodiments;

FIG. 2A illustrates a structure of a power amplifier according to an embodiment;

FIG. 2B illustrates a stacked structure of a power amplifier according to an embodiment;

FIG. 3 illustrates an operational amplifier-based bias circuit for a power amplifier with a 2-stacked structure according to an embodiment;

FIG. 4 illustrates an operational amplifier-based bias circuit for a power amplifier with a 3-stacked structure according to an embodiment;

FIG. 5 illustrates a bias circuit including stacked operational amplifiers according to an embodiment;

FIG. 6 illustrates a power amplifier circuit including a bias circuit with a stacked operational amplifier structure according to an embodiment; and

FIG. 7 illustrates a power amplifier circuit including a bias circuit with a multi-stacked operational amplifier structure according to an embodiment.

### DETAILED DESCRIPTION

Embodiments of the disclosure will be described below in detail with reference to the accompanying drawings. In describing embodiments of the disclosure, a detailed description of related functions or configurations is avoided lest it should obscure the subject matter of the disclosure. The terms described below are terms defined in consideration of the functions in embodiments of the disclosure, and thus may vary depending on the intention of a user or operator or practice. Therefore, the definition should be made based on the entire content of the disclosure.

It should be noted that the technical terms as used in the disclosure are provided merely to describe a specific embodiment, not intended to limit the disclosure. Alternatively, unless otherwise defined, the technical terms as used in the disclosure should be interpreted as the same meanings as generally understood by those skilled in the art, and should not be interpreted as excessively inclusive or excessively narrow meanings. Alternatively, the technical terms used in the disclosure may be understood by being replaced with technical terms that may be understood by those skilled in the art. The general terms used in the disclosure should be interpreted as defined in dictionaries or according to the context, and should not be interpreted as excessively narrow meanings.

Singular forms used in the disclosure include plural referents unless the context clearly dictates otherwise. In this application, the term “have” or “include” should not be interpreted as necessarily including multiple components or operations described in the specification, and should be interpreted as excluding some of the components or operations or further including additional components or operations.

As used herein, the terms “1st” or “first” and “2nd” or “second” may be used to refer to corresponding components regardless of importance or order and used to distinguish a component from another component without limiting the components.

When it is said that a component is “connected to” or “coupled to” another component, the component may be connected or coupled to the other component directly or with a third component in between. On the other hand, when it is said that a component is “directly connected to” or “directly coupled to” another component, it should be understood that there is no third component in between.

Various embodiments of the disclosure will be described in detail with reference to the attached drawings. Like reference numerals are assigned to the same or similar components irrespective of the drawing numbers, and in this regard, a redundant description will be avoided. A detailed description of a known technology will be omitted in describing various embodiments of the disclosure, lest it should obscure the subject matter of the disclosure. Further, it should be noted that the attached drawings are presented merely to help understanding of the spirit of the disclosure, and should not be construed as limiting the spirit of the disclosure. The spirit of the disclosure should be interpreted as encompassing all modifications, equivalents, and alternatives in addition to the attached drawings.

Although an electronic device will be taken as an example in describing embodiments of the disclosure, an electronic device may be referred to as a terminal, a mobile station, a mobile equipment (ME), a user equipment (UE), a user terminal (UT), a subscriber station (SS), a wireless device, a handheld device, and an access terminal (AT). In embodiments of the disclosure, an electronic device may be a device having a communication function, such as a portable phone, a personal digital assistant (PDA), a smartphone, a wireless modem, or a laptop computer.

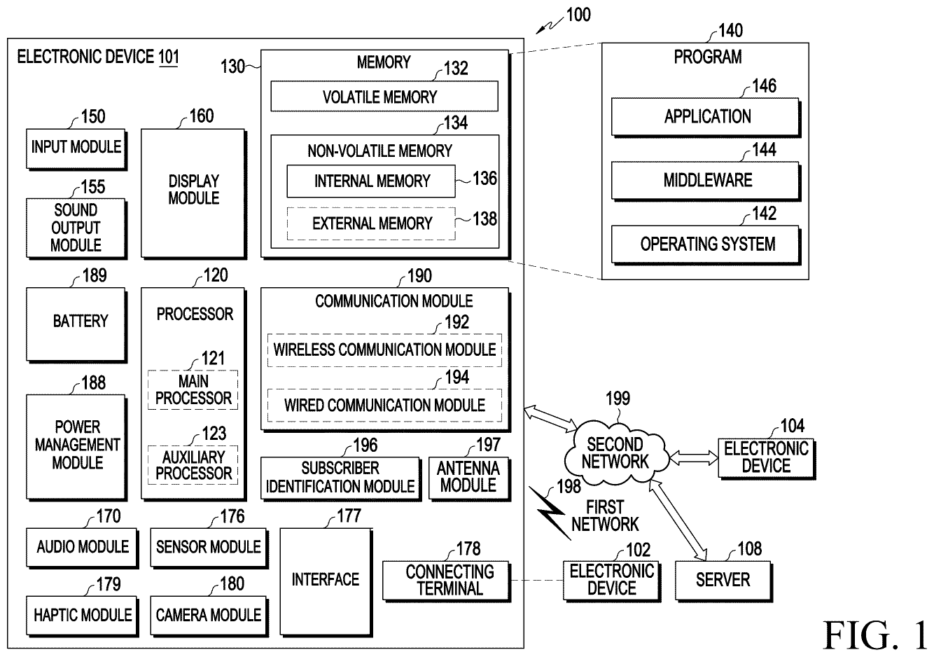

FIG. 1 is a block diagram illustrating an electronic device 101 in a network environment 100 according to various embodiments.

Referring to FIG. 1, the electronic device 101 in the network environment 100 may communicate with an electronic device 102 via a first network 198 (e.g., a short-range wireless communication network), or an electronic device 104 or a server 108 via a second network 199 (e.g., a long-range wireless communication network). According to an embodiment, the electronic device 101 may communicate with the electronic device 104 via the server 108. According to an embodiment, the electronic device 101 may include a processor 120, memory 130, an input module 150, a sound output module 155, a display module 160, an audio module 170, a sensor module 176, an interface 177, a connecting terminal 178, a haptic module 179, a camera module 180, a power management module 188, a battery 189, a communication module 190, a subscriber identification module (SIM) 196, or an antenna module 197. In some embodiments, at least one of the components (e.g., the connecting terminal 178) may be omitted from the electronic device 101, or one or more other components may be added in the electronic device 101. In some embodiments, some of the components (e.g., the sensor module 176, the camera module 180, or the antenna module 197) may be implemented as a single component (e.g., the display module 160).

The processor 120 may execute, for example, software (e.g., a program 140) to control at least one other component (e.g., a hardware or software component) of the electronic device 101 coupled with the processor 120, and may perform various data processing or computation. According to an embodiment, as at least part of the data processing or computation, the processor 120 may store a command or data received from another component (e.g., the sensor module 176 or the communication module 190) in volatile memory 132, process the command or the data stored in the volatile memory 132, and store resulting data in non-volatile memory 134. According to an embodiment, the processor 120 may include a main processor 121 (e.g., a central processing unit (CPU) or an application processor (AP)), or an auxiliary processor 123 (e.g., a graphics processing unit (GPU), a neural processing unit (NPU), an image signal processor (ISP), a sensor hub processor, or a communication processor (CP)) that is operable independently from, or in conjunction with, the main processor 121. For example, when the electronic device 101 includes the main processor 121 and the auxiliary processor 123, the auxiliary processor 123 may be adapted to consume less power than the main processor 121, or to be specific to a specified function. The auxiliary processor 123 may be implemented as separate from, or as part of the main processor 121.

The auxiliary processor 123 may control at least some of functions or states related to at least one component (e.g., the display module 160, the sensor module 176, or the communication module 190) among the components of the electronic device 101, instead of the main processor 121 while the main processor 121 is in an inactive (e.g., sleep) state, or together with the main processor 121 while the main processor 121 is in an active state (e.g., executing an application). According to an embodiment, the auxiliary processor 123 (e.g., an image signal processor or a communication processor) may be implemented as part of another component (e.g., the camera module 180 or the communication module 190) functionally related to the auxiliary processor 123. According to an embodiment, the auxiliary processor 123 (e.g., the neural processing unit) may include a hardware structure specified for artificial intelligence model processing. An artificial intelligence model may be generated by machine learning. Such learning may be performed, e.g., by the electronic device 101 where the artificial intelligence is performed or via a separate server (e.g., the server 108). Learning algorithms may include, but are not limited to, e.g., supervised learning, unsupervised learning, semi-supervised learning, or reinforcement learning. The artificial intelligence model may include a plurality of artificial neural network layers. The artificial neural network may be a deep neural network (DNN), a convolutional neural network (CNN), a recurrent neural network (RNN), a restricted boltzmann machine (RBM), a deep belief network (DBN), a bidirectional recurrent deep neural network (BRDNN), deep Q-network or a combination of two or more thereof but is not limited thereto. The artificial intelligence model may, additionally or alternatively, include a software structure other than the hardware structure.

The memory 130 may store various data used by at least one component (e.g., the processor 120 or the sensor module 176) of the electronic device 101. The various data may include, for example, software (e.g., the program 140) and input data or output data for a command related thereto. The memory 130 may include the volatile memory 132 or the non-volatile memory 134.

The program 140 may be stored in the memory 130 as software, and may include, for example, an operating system (OS) 142, middleware 144, or an application 146.

The input module 150 may receive a command or data to be used by another component (e.g., the processor 120) of the electronic device 101, from the outside (e.g., a user) of the electronic device 101. The input module 150 may include, for example, a microphone, a mouse, a keyboard, a key (e.g., a button), or a digital pen (e.g., a stylus pen).

The sound output module 155 may output sound signals to the outside of the electronic device 101. The sound output module 155 may include, for example, a speaker or a receiver. The speaker may be used for general purposes, such as playing multimedia or playing record. The receiver may be used for receiving incoming calls. According to an embodiment, the receiver may be implemented as separate from, or as part of the speaker.

The display module 160 may visually provide information to the outside (e.g., a user) of the electronic device 101. The display module 160 may include, for example, a display, a hologram device, or a projector and control circuitry to control a corresponding one of the display, hologram device, and projector. According to an embodiment, the display module 160 may include a touch sensor adapted to detect a touch, or a pressure sensor adapted to measure the intensity of force incurred by the touch.

The audio module 170 may convert a sound into an electrical signal and vice versa. According to an embodiment, the audio module 170 may obtain the sound via the input module 150, or output the sound via the sound output module 155 or a headphone of an external electronic device (e.g., an electronic device 102) directly (e.g., wiredly) or wirelessly coupled with the electronic device 101.

The sensor module 176 may detect an operational state (e.g., power or temperature) of the electronic device 101 or an environmental state (e.g., a state of a user) external to the electronic device 101, and then generate an electrical signal or data value corresponding to the detected state. According to an embodiment, the sensor module 176 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 177 may support one or more specified protocols to be used for the electronic device 101 to be coupled with the external electronic device (e.g., the electronic device 102) directly (e.g., wiredly) or wirelessly. According to an embodiment, the interface 177 may include, for example, a high definition multimedia interface (HDMI), a universal serial bus (USB) interface, a secure digital (SD) card interface, or an audio interface.

A connecting terminal 178 may include a connector via which the electronic device 101 may be physically connected with the external electronic device (e.g., the electronic device 102). According to an embodiment, the connecting terminal 178 may include, for example, a HDMI connector, a USB connector, a SD card connector, or an audio connector (e.g., a headphone connector).

The haptic module 179 may convert an electrical signal into a mechanical stimulus (e.g., a vibration or a movement) or electrical stimulus which may be recognized by a user via his tactile sensation or kinesthetic sensation. According to an embodiment, the haptic module 179 may include, for example, a motor, a piezoelectric element, or an electric stimulator.

The camera module 180 may capture a still image or moving images. According to an embodiment, the camera module 180 may include one or more lenses, image sensors, image signal processors, or flashes.

The power management module 188 may manage power supplied to the electronic device 101. According to an embodiment, the power management module 188 may be implemented as at least part of, for example, a power management integrated circuit (PMIC).

The battery 189 may supply power to at least one component of the electronic device 101. According to an embodiment, the battery 189 may include, for example, a primary cell which is not rechargeable, a secondary cell which is rechargeable, or a fuel cell.

The communication module 190 may support establishing a direct (e.g., wired) communication channel or a wireless communication channel between the electronic device 101 and the external electronic device (e.g., the electronic device 102, the electronic device 104, or the server 108) and performing communication via the established communication channel. The communication module 190 may include one or more communication processors that are operable independently from the processor 120 (e.g., the application processor (AP)) and supports a direct (e.g., wired) communication or a wireless communication. According to an embodiment, the communication module 190 may include a wireless communication module 192 (e.g., a cellular communication module, a short-range wireless communication module, or a global navigation satellite system (GNSS) communication module) or a wired communication module 194 (e.g., a local area network (LAN) communication module or a power line communication (PLC) module). A corresponding one of these communication modules may communicate with the external electronic device via the first network 198 (e.g., a short-range communication network, such as BluetoothTM, wireless-fidelity (Wi-Fi) direct, or infrared data association (IrDA)) or the second network 199 (e.g., a long-range communication network, such as a legacy cellular network, a 5G network, a next-generation communication network, the Internet, or a computer network (e.g., LAN or wide area network (WAN)). These various types of communication modules may be implemented as a single component (e.g., a single chip), or may be implemented as multi components (e.g., multi chips) separate from each other. The wireless communication module 192 may identify and authenticate the electronic device 101 in a communication network, such as the first network 198 or the second network 199, using subscriber information (e.g., international mobile subscriber identity (IMSI)) stored in the subscriber identification module 196.

The wireless communication module 192 may support a 5G network, after a 4G network, and next-generation communication technology, e.g., new radio (NR) access technology. The NR access technology may support enhanced mobile broadband (eMBB), massive machine type communications (mMTC), or ultra-reliable and low-latency communications (URLLC). The wireless communication module 192 may support a high-frequency band (e.g., the mmWave band) to achieve, e.g., a high data transmission rate. The wireless communication module 192 may support various technologies for securing performance on a high-frequency band, such as, e.g., beamforming, massive multiple-input and multiple-output (massive MIMO), full dimensional MIMO (FD-MIMO), array antenna, analog beam-forming, or large scale antenna. The wireless communication module 192 may support various requirements specified in the electronic device 101, an external electronic device (e.g., the electronic device 104), or a network system (e.g., the second network 199). According to an embodiment, the wireless communication module 192 may support a peak data rate (e.g., 20Gbps or more) for implementing eMBB, loss coverage (e.g., 164 dB or less) for implementing mMTC, or U-plane latency (e.g., 0.5 ms or less for each of downlink (DL) and uplink (UL), or a round trip of 1 ms or less) for implementing URLLC.

The antenna module 197 may transmit or receive a signal or power to or from the outside (e.g., the external electronic device) of the electronic device 101. According to an embodiment, the antenna module 197 may include an antenna including a radiating element composed of a conductive material or a conductive pattern formed in or on a substrate (e.g., a printed circuit board (PCB)). According to an embodiment, the antenna module 197 may include a plurality of antennas (e.g., array antennas). In such a case, at least one antenna appropriate for a communication scheme used in the communication network, such as the first network 198 or the second network 199, may be selected, for example, by the communication module 190 (e.g., the wireless communication module 192) from the plurality of antennas. The signal or the power may then be transmitted or received between the communication module 190 and the external electronic device via the selected at least one antenna. According to an embodiment, another component (e.g., a radio frequency integrated circuit (RFIC)) other than the radiating element may be additionally formed as part of the antenna module 197.

According to various embodiments, the antenna module 197 may form an mmWave antenna module. According to an embodiment, the mmWave antenna module may include a printed circuit board, a RFIC disposed on a first surface (e.g., the bottom surface) of the printed circuit board, or adjacent to the first surface and capable of supporting a designated high-frequency band (e.g., the mmWave band), and a plurality of antennas (e.g., array antennas) disposed on a second surface (e.g., the top or a side surface) of the printed circuit board, or adjacent to the second surface and capable of transmitting or receiving signals of the designated high-frequency band.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment, commands or data may be transmitted or received between the electronic device 101 and the external electronic device 104 via the server 108 coupled with the second network 199. Each of the electronic devices 102 or 104 may be a device of a same type as, or a different type, from the electronic device 101. According to an embodiment, all or some of operations to be executed at the electronic device 101 may be executed at one or more of the external electronic devices 102, 104, or 108. For example, if the electronic device 101 should perform a function or a service automatically, or in response to a request from a user or another device, the electronic device 101, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and transfer an outcome of the performing to the electronic device 101. The electronic device 101 may provide the outcome, with or without further processing of the outcome, as at least part of a reply to the request. To that end, a cloud computing, distributed computing, mobile edge computing (MEC), or client-server computing technology may be used, for example. The electronic device 101 may provide ultra low-latency services using, e.g., distributed computing or mobile edge computing. In another embodiment, the external electronic device 104 may include an internet-of-things (IoT) device. The server 108 may be an intelligent server using machine learning and/or a neural network. According to an embodiment, the external electronic device 104 or the server 108 may be included in the second network 199. The electronic device 101 may be applied to intelligent services (e.g., smart home, smart city, smart car, or healthcare) based on 5G communication technology or IoT-related technology.

In wireless communication technology, radio frequency (RF) signals in a specified frequency band may be filtered and amplified through a transmission path of a communication circuit (e.g., the wireless communication module 192 in FIG. 1) and then radiated into the air through an antenna (e.g., the antenna module 197 in FIG. 1), or may be received by the antenna (e.g., the antenna module 197 in FIG. 1) and then filtered and amplified through a reception path of the communication circuit (e.g., the wireless communication module 192 in FIG. 1). The transmission path may include one or more power amplifiers to amplify a transmission RF signal to a desired power level.

Embodiments may provide a circuit structure for implementing a complementary metal-oxide-semiconductor (CMOS) field-effect transistor (MOSFET)-based high-power power amplifier to implement beamforming technology in a frequency band such as mmWave above 10 GHz. A CMOS device has difficulty in producing high output due to a low power supply voltage V_{DD}. To improve this, multiple transistors may be stacked to increase the power supply voltage and the magnitude of a maximum output signal.

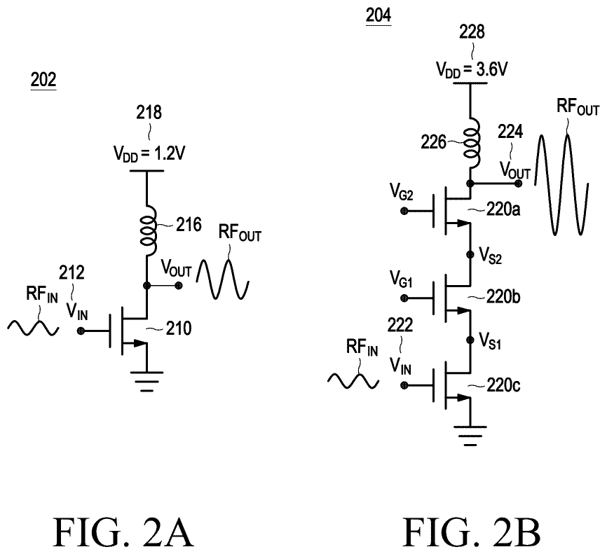

FIG. 2A illustrates a structure of a power amplifier according to an embodiment.

Referring to FIG. 2A, a power amplifier 202 may include a single transistor 210 including a gate node, a drain node, and a source node. The gate node may be connected to an input signal RF_{IN} (e.g., V_{IN} 212), the drain node may be connected to an output signal RF_{OUT} (e.g., V_{OUT} 214), and the source node may be connected to a ground (GND). The drain node may receive a power supply voltage V_{DD} 218 (e.g., 1.2 V) through an inductor coil 216. The transistor 210 may amplify the input signal RF_{IN} (e.g., V_{IN} 212) provided to the gate node and output an amplified signal corresponding to the input signal, that is, the output signal RF_{OUT} (e.g., V_{OUT} 214), through the drain node.

FIG. 2B illustrates a stacked structure of a power amplifier according to an embodiment.

Referring to FIG. 2B, a power amplifier 204 with a stacked structure may include one or more transistors (e.g., a first transistor 220a, a second transistor 220b, and a third transistor 220c connected in a stacked cascode structure between a power supply voltage V_{DD} 228 and a GND), each including a gate node, a drain node, and a source node.

In an embodiment, the source node of the first transistor 220a is connected to the drain node of the second transistor 220b, and the source node of the second transistor 220b is connected to the drain node of the third transistor 220c. Thus, the first transistor 220a, the second transistor 220b, and the third transistor 220c may form a stacked cascode structure. The drain node of the first transistor 220a may receive the power supply voltage V_{DD} 228 (e.g., 3.6 V) through an inductor coil 226, and the source node of the third transistor 220c may be connected to the GND.

In an embodiment, the drain node of the first transistor 220a may be connected to an output signal RF_{OUT} (e.g., V_{OUT} 224), and the gate node of the third transistor 220c may be connected to an input signal RF_{IN} (e.g., V_{IN} 222). The input signal RF_{IN} (e.g., V_{IN} 222) provided to the gate node of the third transistor 220c may be amplified by the third transistor 220c, the second transistor 220b, and the first transistor 220a, and the amplified signal corresponding to the input signal, that is, the output signal RF_{OUT} (e.g., V_{OUT} 224), may be output through the drain node of the first transistor 220a.

In an embodiment, the power amplifier 204 including the three stacked transistors 220a, 220b, and 220c may use a power supply voltage (e.g., V_{DD} 228=3.6 V) that is three times higher than that of the power amplifier 202 including the single transistor 210 (e.g., V_{DD} 218=1.2 V), and thus provide a higher output voltage (e.g., V_{OUT} 224) for the same input voltage (e.g., V_{IN} 222).

Embodiments may generate one or more additional bias voltages to supply power to multiple transistors that form a stacked power amplifier. Embodiments may use at least one operational amplifier (OP AMP) to supply bias voltages to the transistors of the stacked power amplifier.

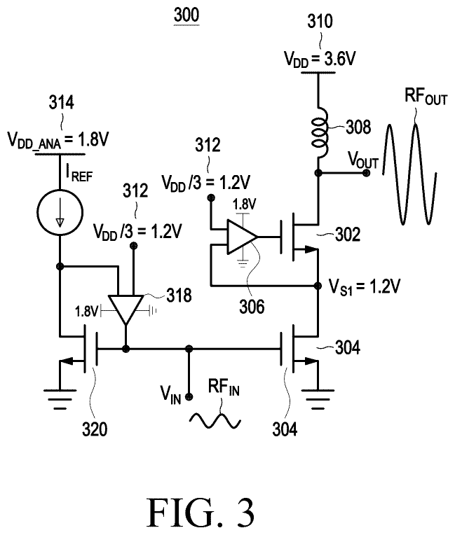

FIG. 3 illustrates an OP AMP-based bias circuit for a power amplifier with a 2-stacked structure according to an embodiment.

Referring to FIG. 3, a power amplifier 300 with a 2-stacked structure may include one or more transistors (e.g., a first transistor 302 and a second transistor 304 connected between a power supply voltage V_{DD} 310 and a GND), each including a gate node, a drain node, and a source node, and an operational amplifier (OP AMP) 306 for providing a bias voltage to the first transistor 302.

In an embodiment, the source node of the first transistor 302 may be connected to the drain node of the second transistor 304. The drain node of the first transistor 302 may receive the power supply voltage V_{DD} 310 (e.g., 3.6 V) through an inductor coil 308, and the source node of the second transistor 304 may be connected to the GND.

In an embodiment, the drain node of the first transistor 302 may be connected to an output signal RF_{OUT} (e.g., V_{OUT}), and the gate node of the second transistor 304 may be connected to an input signal RF_{IN} (e.g., V_{IN}). The input signal RF_{IN} provided to the gate node of the second transistor 304 may be amplified by the second transistor 304 and the first transistor 302, and the amplified signal corresponding to the input signal, that is, the output signal RF_{OUT}, may be output through the drain node of the first transistor 302.

In an embodiment, the OP AMP 306 may include a positive (i.e., non-inverting) input terminal connected to a three-divided power supply voltage V_{DD}/3 312 (e.g., 1.2 V) generated from the power supply voltage V_{DD} 310, a negative (i.e., inverting) input terminal connected to the source node of the first transistor 302 and the drain node of the second transistor 304, and an output terminal connected to the gate node of the first transistor 302. The OP AMP 306 may generate a bias voltage for the first transistor 302 based on the three-divided power supply voltage V_{DD}/3 312 and output the bias voltage to the gate node of the first transistor 302. The OP AMP 306 may be driven by receiving a power supply voltage (e.g., an analog power supply voltage V_{DD_ANA} 314 (e.g., 1.8 V)) for an analog circuit through a power supply terminal.

In an embodiment, the power amplifier 300 may further include a mirror transistor 320 corresponding to the second transistor 304. The mirror transistor 320 may include a gate node connected to the gate node of the second transistor 304, a drain node connected to the analog power supply voltage V_{DD_ANA} 314 (e.g., 1.8 V), and a source node connected to the GND. An OP AMP 318 that provides a bias voltage for the mirror transistor 320 may be connected to the gate node of the mirror transistor 320.

In an embodiment, the OP AMP 318 may include a positive input terminal connected to the three-divided power supply voltage V_{DD}/3 312 (e.g., 1.2 V), a negative input terminal connected to the drain node of the mirror transistor 320, and an output terminal connected to the gate node of the mirror transistor 320. The OP AMP 318 may generate a bias voltage for the mirror transistor 320 based on the three-divided power supply voltage V_{DD}/3 312 and output the bias voltage to the gate node of the mirror transistor 320. The OP AMP 318 may be driven by receiving the analog power supply voltage V_{DD_ANA} 314 (e.g., 1.8 V) through a power supply terminal.

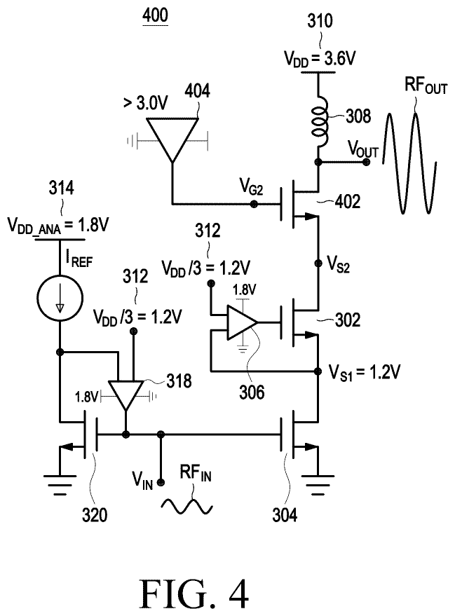

FIG. 4 illustrates an OP AMP-based bias circuit for a power amplifier with a 3-stacked structure according to an embodiment.

Referring to FIG. 4, a power amplifier 400 with a 3-stacked structure includes one or more transistors (e.g., a third transistor 402, the first transistor 302, and the second transistor 304 connected between the power supply voltage V_{DD} 310 and a GND), each including a gate node, a drain node, and a source node, and one or more OP AMPs (e.g., the OP AMP 306 and an OP AMP 404) for providing bias voltages to the first transistor 302 and the third transistor 402.

In an embodiment, the source node of the third transistor 402 may be connected to the drain node of the first transistor 302, and the source node of the first transistor 302 may be connected to the drain node of the second transistor 304. The drain node of the third transistor 402 may receive the power supply voltage V_{DD} 310 (e.g., 3.6 V) through the inductor coil 308, and the source node of the second transistor 304 may be connected to the GND.

In an embodiment, the drain node of the third transistor 402 may be connected to an output signal RF_{OUT} (e.g., V_{OUT}), and the gate node of the second transistor 304 may be connected to an input signal RF_{IN} (e.g., V_{IN}). The input signal RF_{IN} provided to the gate node of the second transistor 304 may be amplified by the second transistor 304, the first transistor 302, and the third transistor 402, and the amplified signal corresponding to the input signal, that is, the output signal RF_{OUT}, may be output through the drain node of the third transistor 402.

In an embodiment, the positive input terminal of the OP AMP 306 may be connected to the three-divided power supply voltage V_{DD}/3 312 (e.g., 1.2 V) generated from the power supply voltage V_{DD} 310, the negative input terminal of the OP AMP 306 may be connected to the source node of the first transistor 302 and the drain node of the second transistor 304, and the output terminal of the OP AMP 306 may be connected to the gate node of the first transistor 302. The OP AMP 306 may generate the bias voltage for the first transistor 302 based on the three-divided power supply voltage V_{DD}/3 312 and output the bias voltage to the gate node of the first transistor 302. The OP AMP 306 may be driven by receiving the analog power supply voltage V_{DD_ANA} 314 (e.g., 1.8 V) through the power supply terminal.

In an embodiment, the power amplifier 400 may further include the mirror transistor 320 corresponding to the second transistor 304. The mirror transistor 320 may include the gate node connected to the gate node of the second transistor 304, the drain node connected to the analog power supply voltage V_{DD_ANA} 314 (e.g., 1.8 V), and the source node connected to the GND. The OP AMP 318 that provides a bias voltage for the mirror transistor 320 may be connected to the gate node of the mirror transistor 320.

In an embodiment, the positive input terminal of the OP AMP 318 may be connected to the three-divided power supply voltage V_{DD}/3 312 (e.g., 1.2 V), the negative input terminal of the OP AMP 318 may be connected to the drain node of the mirror transistor 320, and the output terminal of the OP AMP 318 may be connected to the gate node of the mirror transistor 320. The OP AMP 318 may generate a bias voltage for the mirror transistor 320 based on the three-divided power supply voltage V_{DD}/3 312 and output the bias voltage to the gate node of the mirror transistor 320. The OP AMP 318 may be driven by receiving the analog power supply voltage V_{DD_ANA} 314 (e.g., 1.8 V) through the power supply terminal.

In an embodiment, the power amplifier 400 may further include the OP AMP 404 for providing a bias voltage for the third transistor 402. The OP AMP 404 may be configured to provide a higher bias voltage for the third transistor 402 than the bias voltage for the first transistor 302.

In an embodiment, the power amplifier 400 including three transistors (e.g., the third transistor 402, the first transistor 302, and the second transistor 304) needs to appropriately receive voltages (e.g., V_{G1}, V_{S1}, V_{G2}, and V_{S2}) for upper-stack transistors (e.g., the third transistor 402 and the first transistor 302), compared to the power amplifier 300 including two transistors (e.g., the first transistor 302 and the second transistor 304). In an embodiment, because a source voltage V_{S1} of the first transistor 302 is 1.2 V and a source voltage V_{S2} of the third transistor 402 is 2.4 V, the third transistor 402 may require a bias voltage V_{G2} higher than 2.4V. For the high bias voltage V_{G2}, the OP AMP 404 may require a higher additional power supply voltage in addition to the reference power supply voltage V_{DD} 310 (e.g., 3.6 V) or the analog power supply voltage V_{DD_ANA} 314.

The use of an additional element (e.g., the OP AMP 404) for biasing power amplifier transistors (e.g., the third transistor 402 and the first transistor 302) imposes a very large burden on the configuration of an entire system. In particular, in a communication circuit with a phased array structure for using beamforming, a large number of power amplifiers (e.g., the power amplifier 400) are integrated within one chip, thereby further increasing the burden of using an additional element (e.g., an OP AMP) for each power amplifier.

In an embodiment, because the power amplifier 300 with a 2-stacked structure includes one stacked transistor (e.g., the first transistor 302) excluding the second transistor 304 for signal input, and the bias voltage required for the first transistor 302 is 1.2 V, the power amplifier 300 may provide the bias voltage to the first transistor 302 through the OP AMP 306 driven by the analog power supply voltage V_{DD_ANA} 314 (e.g., 1.8 V). As the number of stacked transistors increases, a transistor in a higher stack (e.g., the third transistor 402 in FIG. 4) may require a higher bias voltage than a transistor in a lower stack (e.g., the first transistor 302 in FIG. 3).

In an embodiment, the power amplifier 400 with a 3-stacked structure includes two stacked transistors (e.g., the first transistor 302 and the third transistor 402) excluding the second transistor 304 for signal input, and the third transistor 402 in the highest stack requires a source voltage V_{S2} of 2.4 V and a gate voltage V_{G2} higher than 2.4 V. For the source voltage V_{S2} and the gate voltage V_{G2}, a bias circuit including an OP AMP (e.g., the OP AMP 404) operating at a power supply voltage higher than the analog circuit voltage V_{DD_ANA} 314 (e.g., 1.8 V) (e.g., higher than 3.0 V) may be additionally designed. The bias circuit operating at the higher power supply voltage may require high-voltage transistors such as lateral double diffused MOS (LDMOS), and the use of such high-voltage transistors may increase the production cost of the communication circuit.

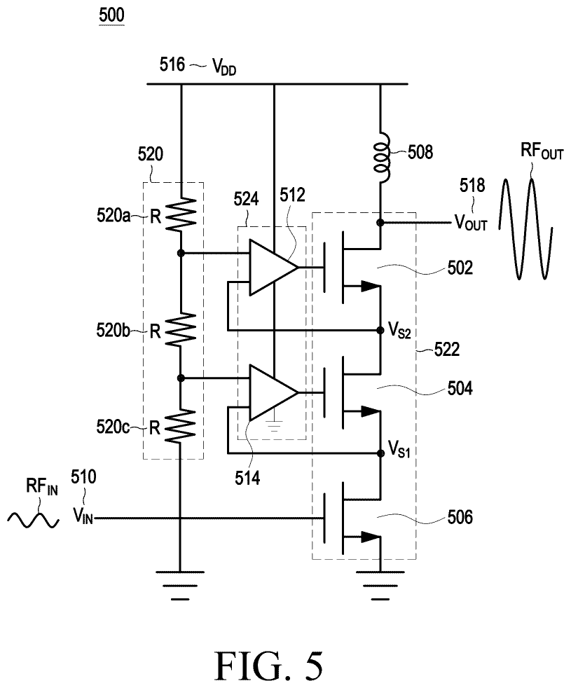

Embodiments may generate bias voltages for transistors (e.g., transistors 502 and 504 in FIG. 5) that form a stacked power amplifier without using an additional power supply voltage (e.g., the analog power supply voltage 314) in addition to the reference power supply voltage (e.g., the power supply voltage V_{DD}). Embodiments may efficiently provide higher bias voltages to transistors included in a stacked power amplifier by configuring OP AMPs (e.g., OP AMPs 512 and 514 in FIG. 5) included in a bias circuit for the stacked power amplifier in a stacked structure.

FIG. 5 illustrates a bias circuit including stacked OP AMPs according to an embodiment.

Referring to FIG. 5, a power amplifier 500 may include an amplifier circuit 522 and a bias circuit 524. The amplifier circuit 522 may include a first transistor 502, a second transistor 504, and a third transistor 506 connected in a stacked cascode structure between a power supply voltage V_{DD} 516 (e.g., 3.6 V) and a GND. The bias circuit 524 may include a first OP AMP 512 and a second OP AMP 514 that provide a first bias voltage and a second bias voltage to the first transistor 502 and the second transistor 504, respectively.

In an embodiment, each of the first transistor 502, the second transistor 504, and the third transistor 506 may be a field effect transistor (FET) including a gate node, a source node, and a drain node. As the source node of the first transistor 502 is connected to the drain node of the second transistor 504, and the source node of the second transistor 504 is connected to the drain node of the third transistor 506, the first transistor 502, the second transistor 504, and the third transistor 506 may form a stacked cascode structure. The drain node of the first transistor 502 may receive the power supply voltage V_{DD} 516 through an inductor coil 508, and the source node of the third transistor 506 may be connected to the GND (e.g., alternating current (AC) ground).

In an embodiment, an input signal RF_{IN} (e.g., an input voltage V_{IN} 510) for the power amplifier 500 may be provided to the gate node of the third transistor 506 and amplified by the amplifier circuit 522 (e.g., the third transistor 506, the second transistor 504, and the first transistor 502). An output signal RF_{OUT} (e.g., an output voltage V_{OUT} 518) corresponding to the input voltage V_{IN} 510 may be provided to the drain node of the first transistor 502.

In an embodiment, the first OP AMP 512 may include a positive input terminal connected to a reference voltage (e.g., V_{DD}×2/3) divided from the power supply voltage V_{DD} 516, a negative input terminal connected to the source node of the first transistor 502 and the drain node of the second transistor 504, an output terminal connected to the gate node of the first transistor 502 to provide the first bias voltage, a power supply terminal (i.e., positive power supply terminal) connected to the power supply voltage V_{DD} 516, and a ground terminal (i.e., negative power supply terminal). In an embodiment, the first OP AMP 512 may receive a power supply voltage (e.g., 2.4 V) divided from the power supply voltage V_{DD} 516 at the positive input terminal of the first OP AMP 512, and the ground terminal of the first OP AMP 512 may provide a voltage of 1.8 V and be connected to a power supply terminal of the second OP AMP 514.

In an embodiment, the second OP AMP 514 may include a positive input terminal connected to a second reference voltage (e.g., V_{DD}×1/3) divided from the power supply voltage V_{DD} 516, a negative input terminal connected to the source node of the second transistor 504 and the drain node of the third transistor 506, an output terminal connected to the gate node of the second transistor 504 to provide the second bias voltage, a power supply terminal connected to the ground terminal of the first OP AMP 512, and a ground terminal. In an embodiment, the second OP AMP 514 may receive a power supply voltage (e.g., 1.2 V) divided from the power supply voltage V_{DD} 516 at the positive input terminal of the second OP AMP 514, and the ground terminal of the second OP AMP 514 may be grounded.

In an embodiment, the power supply voltage V_{DD} 516 may be divided by a resistor ladder 520 (e.g., a resistive voltage divider) including resistors connected in series (e.g., a first resistor 520a, a second resistor 520b, and a third resistor 520c), and the divided voltages may be provided to the positive input terminals of the first OP AMP 512 and the second OP AMP 514. In an embodiment, the first resistor 520a, the second resistor 520b, and the third resistor 520c may be serially connected between the power supply voltage V_{DD} 516 and the GND. In an embodiment, the positive input terminal of the first OP AMP 512 may be connected between the first resistor 520a and the second resistor 520b. In an embodiment, the positive input terminal of the second OP AMP 514 may be connected between the second resistor 520b and the third resistor 520c. In an embodiment, the gate node of the third transistor 506 may be connected between the third resistor 520c and the GND.

In an embodiment, resistance values of the first resistor 520a, the second resistor 520b, and the third resistor 520c may be set to the same value. Therefore, the first transistor 502, the second transistor 504, and the third transistor 506 may have equal drain-source voltages. In an embodiment, at least one of the first resistor 520a, the second resistor 520b, or the third resistor 520c may be configured as a configurable (i.e., variable) resistor.

The resistance value of at least one of the first resistor 520a, the second resistor 520b, or the third resistor 520c may be set to a different value according to a required gate voltage for at least one of the first transistor 502, the second transistor 504, or the third transistor 506.

In an embodiment, the first resistor 520a, the second resistor 520b, and the third resistor 520c set to the same values, and the power supply voltage V_{DD} 516 may be 3.6 V. Therefore, a voltage of 2.4 V may be provided to the positive input terminal of the first OP AMP 512 and a voltage of 1.2 V may be provided to the positive input terminal of the second OP AMP 514. By utilizing virtual shorts and high input impedances of the first OP AMP 512 and the second OP AMP 514, the negative input terminal of the first OP AMP 512 may be connected to a junction between the source node of the first transistor 502 and the drain node of the second transistor 504 to supply V_{S2}, and the negative input terminal of the second OP AMP 514 may be connected to a junction between the source node of the second transistor 504 and the drain node of the third transistor 506 to supply V_{S1}.

In an embodiment, because the first transistor 502, the second transistor 504, and the third transistor 506 have the same drain-source voltage and drain-source current, gate-source voltages of the first transistor 502, the second transistor 504, and the third transistor 506 are also the same, and the first transistor 502, the second transistor 504, and the third transistor 506 may use the same gate voltages.

In an embodiment, the power amplifier 500 may avoid using an additional high power supply voltage or an OP AMP device operating at a high power supply voltage by connecting the first OP AMP 512 and the second OP AMP 514 in a stacked structure, and driving both the first OP AMP 512 and the second OP AMP 514 using a single power supply voltage (e.g., V_{DD} 516). In an embodiment, the first OP AMP 512 and the second OP AMP 514 may be configured as the same type of OP AMPs, thereby reducing the design complexity of the power amplifier 500.

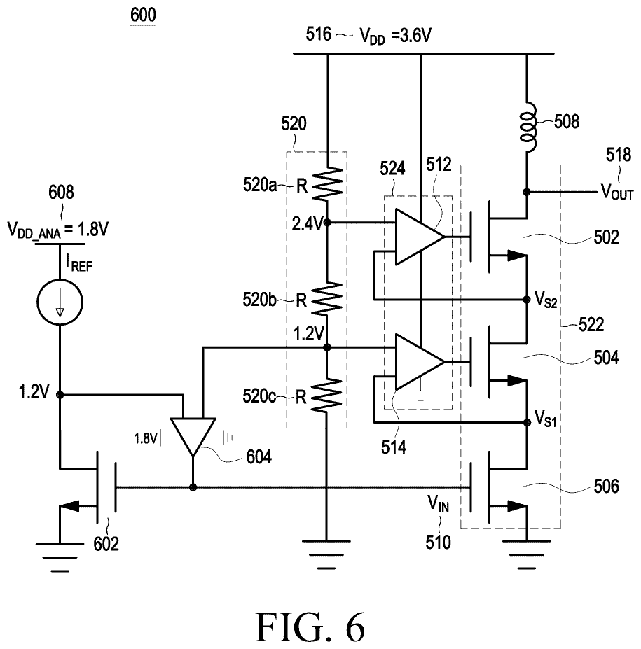

FIG. 6 illustrates a power amplifier circuit including a bias circuit with a stacked OP AMP structure according to an embodiment.

Referring to FIG. 6, a power amplifier 600 may include the amplifier circuit 522 and the bias circuit 524. The amplifier circuit 522 may include the first transistor 502, the second transistor 504, and the third transistor 506 connected in a stacked cascode structure between the power supply voltage V_{DD} 516 (e.g., 3.6 V) and the GND. The bias circuit 524 may include the first OP AMP 512 and the second OP AMP 514 that provide a first bias voltage and a second bias voltage to the first transistor 502 and the second transistor 504, respectively. In an embodiment, the power amplifier 600 may further include the resistor ladder 520 including resistors (e.g., the first resistor 520a, the second resistor 520b, and the third resistor 520c) connected in series between the power supply voltage V_{DD} 516 and the GND. The amplifier circuit 522, the bias circuit 524, and the resistor ladder 520, may be substantially similar to the description provided above with reference to FIG. 5.

In an embodiment, the power amplifier 600 may further include a mirror transistor 602 corresponding to the third transistor 506. The mirror transistor 602 may include a gate node connected to the gate node of the third transistor 506, a drain node connected to a reference current source provided with an analog power supply voltage V_{DD_ANA} 608 (e.g., 1.8 V), and a source node connected to the GND. An OP AMP 604 that provides a bias voltage for the mirror transistor 602 may be connected to the gate node of the mirror transistor 602. In this regard, the drain node of the mirror transistor 602 may be provided with 1.2 V.

In an embodiment, the OP AMP 604 may include a positive input terminal connected between the second resistor 520b and the third resistor 520c of the resistor ladder 520, a negative input terminal connected to the drain node of the mirror transistor 602, and an output terminal connected to the gate node of the mirror transistor 602. The OP AMP 604 may generate a bias voltage for the mirror transistor 602 based on a three-divided power supply voltage V_{DD}/3 (e.g., 1.2 V) provided from a junction between the second resistor 520b and the third resistor 520c and output the bias voltage to the gate node of the mirror transistor 602. The OP AMP 604 may receive the analog power supply voltage V_{DD_ANA} 608 (e.g., 1.8 V) as an input through the power supply terminal and be driven by the analog power supply voltage.

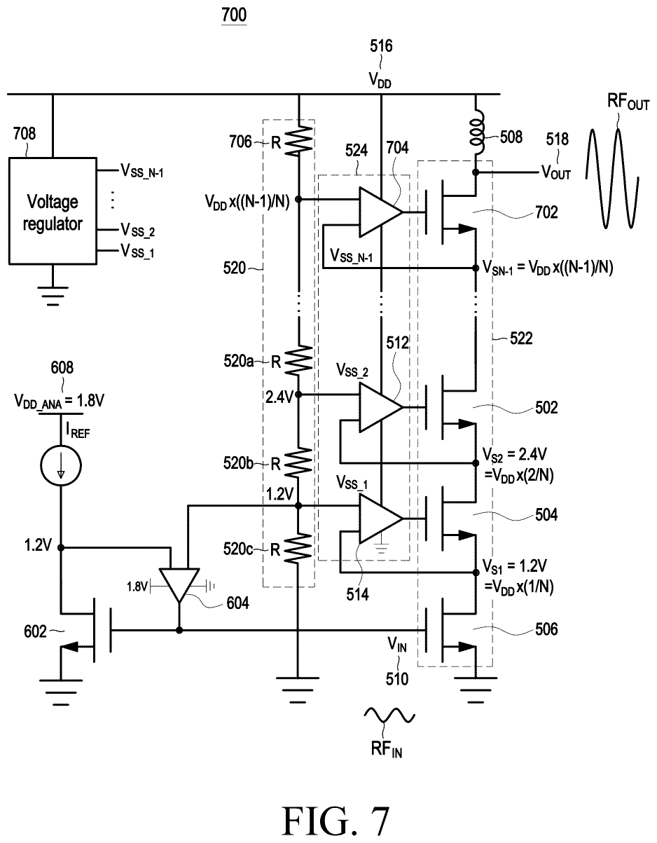

FIG. 7 illustrates a power amplifier circuit including a bias circuit with a multi-stacked OP AMP structure according to an embodiment.

Referring to FIG. 7, a power amplifier 700 may include the amplifier circuit 522 and the bias circuit 524. The amplifier circuit 522 may include the first transistor 502, the second transistor 504, and the third transistor 506, as well as at least one additional stacked transistor (e.g., a fourth transistor 702), connected in a stacked cascode structure between the power supply voltage V_{DD} 516 (e.g., 3.6 V) and the GND. The bias circuit 524 may include at least one additional OP AMP (e.g., a third OP AMP 704), the first OP AMP 512, and the second OP AMP 514 that provide a third bias voltage, a first bias voltage, and a second bias voltage to the fourth transistor 702, the first transistor 502, and the second transistor 504, respectively. In an embodiment, the amplifier circuit 522 may be configured as an N-stacked power amplifier, and the bias circuit 524 may include (N-1)-stacked OP AMPs.

In an embodiment, the power amplifier 700 may further include the resistor ladder 520 including N resistors (e.g., a fourth resistor 706, the first resistor 520a, the second resistor 520b, and the third resistor 520c) connected in series between the power supply voltage V_{DD} 516 and the GND. The first transistor 502, the second transistor 504, and the third transistor 506, may be substantially similar to the description provided above with reference to FIG. 5. The first OP AMP 512, the second OP AMP 514, the first resistor 520a, the second resistor 520b, and the third resistor 520c, may be substantially similar to the description provided above with reference to FIG. 5.

In an embodiment, a drain node of the fourth transistor 702 may receive the power supply voltage 516 through the inductor coil 508, and a source node of the fourth transistor 702 may be connected to the drain node of the first transistor 502, so that the fourth transistor 702, the first transistor 502, the second transistor 504, and the third transistor 506 may form a stacked cascode structure.

In an embodiment, an input signal RF_{IN} (e.g., the input voltage V_{IN} 510) for the power amplifier 700 may be provided to the gate node of the third transistor 506 and amplified by the amplifier circuit 522 (e.g., the third transistor 506, the second transistor 504, the first transistor 502, and the fourth transistor 702). An output signal RF_{OUT} (e.g., the output voltage V_{OUT} 518) corresponding to the input voltage V_{IN} 510 may be provided to the drain node of the fourth transistor 702.

In an embodiment, the third OP AMP 704 may include a positive input terminal connected to a reference voltage (e.g., V_{DD}×((N−1)/N)) divided from the power supply voltage V_{DD} 516, a negative input terminal connected to the source node of the fourth transistor 702 and the drain node of the first transistor 502, an output terminal connected to the gate node of the fourth transistor 702 to provide the third bias voltage, a power supply terminal connected to the power supply voltage V_{DD} 516, and a ground terminal. In an embodiment, the third OP AMP 704 may receive the power supply voltage (e.g., VDD×((N−1)/N)) divided from the power supply voltage V_{DD} 516 at the positive input terminal, and the ground terminal of the third OP AMP 704 may be connected to the power supply terminal of the first OP AMP 512.

In an embodiment, the power supply voltage V_{DD} 516 may divided by the resistor ladder 520 including the serially connected resistors (e.g., the fourth resistor 706, the first resistor 520a, the second resistor 520b, and the third resistor 520c) and provided to the positive input terminals of the third OP AMP 704, the first OP AMP 512, and the second OP AMP 514. In an embodiment, the positive input terminal of the third OP AMP 704 may be connected between the fourth resistor 706 and the first resistor 520a.

In an embodiment, the power amplifier 700 may further include the mirror transistor 602 corresponding to the third transistor 506. The mirror transistor 602 may include the gate node connected to the gate node of the third transistor 506, the drain node connected to a reference current source provided with the analog power supply voltage V_{DD_ANA} 608 (e.g., 1.8 V), and the source node connected to the GND. The OP AMP 604 that provides a bias voltage for the mirror transistor 602 may be connected to the gate node of the mirror transistor 602. In this regard, the drain node of the mirror transistor 602 may be provided with 1.2 V.

In an embodiment, the positive input terminal of the OP AMP 604 may be connected between the second resistor 520b and the third resistor 520c of the resistor ladder 520, the negative input terminal of the OP AMP 604 may be connected to the drain node of the mirror transistor 602, and the output terminal of the OP AMP 604 may be connected to the gate node of the mirror transistor 602. The OP AMP 604 may generate a bias voltage for the mirror transistor 602 based on an N-divided power supply voltage V_{DD}/N (e.g., 1.2 V) provided from the junction between the second resistor 520b and the third resistor 520c, and output the bias voltage to the gate node of the mirror transistor 602. The OP AMP 604 may receive the analog power supply voltage V_{DD_ANA} 608 (e.g., 1.8 V) as an input through the power supply terminal and be driven by the analog power supply voltage.

In an embodiment, the power amplifier 700 may further include a voltage regulator 708 configured to generate source voltages (e.g., V_{SS_N-1}, V_{SS_2}, and V_{SS_1}) to be provided as power supply voltages to the remaining OP AMPs (e.g., the first OP AMP 512 and the second OP AMP 514) excluding the third OP AMP 704 (i.e., the topmost stacked OP AMP). The voltage regulator 708 may generate these source voltages based on the power supply voltage V_{DD} 516. The use of the voltage regulator 708 may enable the power amplifier 700 to operate the OP AMPs (e.g., the third OP AMP 704, the first OP AMP 512, and the second OP AMP 514) without using an additional power supply voltage for the bias circuit 524 in addition to the power supply voltage V_{DD} 516 and the analog power supply voltage V_{DD_ANA} 608.

The power amplifier 500 according to an embodiment may include the amplifier circuit 522 comprising the first transistor 502, the second transistor 504, and the third transistor 506 connected in a stacked cascode structure between the power supply voltage 516 and the ground, and the bias circuit 524 comprising the first operational amplifier 512 configured to provide a first bias voltage to the first transistor, and the second operational amplifier 514 configured to provide a second bias voltage to the second transistor. The first operational amplifier may comprise a positive input terminal connected to a first reference voltage divided from the power supply voltage, a negative input terminal connected to a source node of the first transistor, an output terminal configured to provide the first bias voltage to a gate node of the first transistor, a positive power supply terminal connected to the power supply voltage, and a negative power supply terminal. The second operational amplifier may comprise a positive input terminal connected to a second reference voltage divided from the power supply voltage, a negative input terminal connected to a source node of the second transistor, an output terminal configured to provide the second bias voltage to a gate node of the second transistor, a positive power supply terminal connected to the negative power supply terminal of the first operational amplifier, and a negative power supply terminal connected to the ground.

In an embodiment, the power amplifier may further comprise a resistor ladder including the first resistor 520a, the second resistor 520b, and the third resistor 520c connected in series between the power supply voltage and the ground. The positive input terminal of the first operational amplifier may be connected to the resistor ladder between the first resistor and the second resistor, and the positive input terminal of the second operational amplifier may be connected to the resistor ladder between the second resistor and the third resistor.

In an embodiment, at least one of the first resistor, the second resistor, or the third resistor may be a variable resistor.

In an embodiment, an RF signal may be received through a gate node of the third transistor, and an amplified output RF signal corresponding to the input RF signal may be output through a drain node of the first transistor.

In an embodiment, the power amplifier may further comprises an inductor coil connected between the power supply voltage and the drain node of the first transistor.

In an embodiment, the amplifier circuit may further comprise a fourth transistor 702 connected to the first transistor in a stacked cascode structure. The bias circuit further may further comprise a third operational amplifier 704 configured to provide a bias voltage to the fourth transistor.

In an embodiment, the power amplifier may further include the voltage regulator 708 configured to generate source voltages to be provided to the first operational amplifier and the second operational amplifier, based on the power supply voltage.

In an embodiment, the power amplifier may further include an analog bias circuit comprising the mirror transistor 602 corresponding to the third transistor and the third operational amplifier 604 configured to provide a third bias voltage to the mirror transistor.

The third operational amplifier may comprise a positive input terminal connected to an analog power supply voltage, a negative input terminal connected to the positive input terminal of the second operational amplifier, a positive power supply terminal connected to the analog power supply voltage, and a negative power supply terminal connected to the ground. The mirror transistor may comprise a gate node connected to the gate node of the third transistor, a drain node connected to the analog power supply voltage via a reference current source, and a source node connected to the ground.

In an embodiment, the first transistor, the second transistor, and the third transistor may be complementary metal-oxide-semiconductor MOS CMOS transistors.

In an embodiment, the amplifier circuit may be configured to be used in a transmission path of an RF communication circuit configured to support a millimeter wave (mmWave) frequency band.

In a communication circuit including a transmission path according to an embodiment, the transmission path may comprise one or more power amplifiers. Among the one or more power amplifiers, at least one power amplifier 500 may comprise the amplifier circuit 522 comprising the first transistor 502, the second transistor 504, and the third transistor 506 connected in a stacked cascode structure between the power supply voltage 516 and the ground, and the bias circuit 524 comprising the first operational amplifier 512 configured to provide a first bias voltage to the first transistor, and the second operational amplifier 514 configured to provide a second bias voltage to the second transistor. The first operational amplifier may comprise a positive input terminal connected to a first reference voltage divided from the power supply voltage, a negative input terminal connected to a source node of the first transistor, an output terminal configured to provide the first bias voltage to a gate node of the first transistor and configured to provide the first bias voltage, a positive power supply terminal connected to the power supply voltage, and a negative power terminal. The second operational amplifier may comprise a positive input terminal connected to a second reference voltage divided from the power supply voltage, a negative input terminal connected to a source node of the second transistor, an output terminal configured to provide the second bias voltage to a gate node of the second transistor, a positive power supply terminal connected to the negative power supply terminal of the first operational amplifier, and a negative power supply terminal connected to the ground.

In an embodiment, the at least one power amplifier may further comprise a resistor ladder including the first resistor 520a, the second resistor 520b, and the third resistor 520c connected in series between the power supply voltage and the ground. The positive input terminal of the first operational amplifier may be connected to the resistor ladder between the first resistor and the second resistor, and the positive input terminal of the second operational amplifier may be connected to the resistor ladder between the second resistor and the third resistor.

In an embodiment, at least one of the first resistor, the second resistor, or the third resistor may be a variable resistor.

In an embodiment, an input RF signal may be received through a gate node of the third transistor, and an amplified output RF signal corresponding to the input RF signal may be output through a drain node of the first transistor.

In an embodiment, the at least one power amplifier may further comprise an inductor coil connected between the power supply voltage and the drain node of the first transistor.

In an embodiment, the amplifier circuit may further comprise a fourth transistor 702 connected to the first transistor in a stacked cascode structure. The bias circuit may further comprise a third operational amplifier 704 configured to provide a bias voltage to the fourth transistor.

In an embodiment, the at least one power amplifier may further include a voltage regulator 708 configured to generate source voltages to be provided to the first operational amplifier and the second operational amplifier, based on the power supply voltage.

In an embodiment, the at least one power amplifier may further comprise an analog bias circuit comprising the mirror transistor 602 corresponding to the third transistor and the third operational amplifier 604 configured to provide a third bias voltage to the mirror transistor. The third operational amplifier may comprise a positive input terminal connected to an analog power supply voltage, a negative input terminal connected to the positive input terminal of the second operational amplifier, a positive power supply terminal connected to the analog power supply voltage, and a negative power supply terminal connected to the ground. The mirror transistor may comprise a gate node connected to the gate node of the third transistor, a drain node connected to the analog power supply voltage via a reference current source, and a source node connected to the ground.

In an embodiment, the first transistor, the second transistor, and the third transistor may be CMOS transistors.

In an embodiment, the transmission path may be configured to support an mmWave frequency band.

According to embodiments of the disclosure, a power amplifier includes: a first transistor, a second transistor and a third transistor connected in series between a power supply voltage and a ground, wherein a drain of the first transistor is configured to provide an amplified voltage based on an input voltage at a gate of the third transistor; a first operational amplifier configured to provide a first bias voltage to the first transistor; a second operational amplifier configured to provide a second bias voltage to the second transistor; and a first resistor, a second resistor and a third resistor connected in series between the power supply voltage and the ground.

A positive power supply terminal of the first operational amplifier may be connected to the power supply voltage, and a positive power supply terminal of the second operational amplifier may be connected to a negative power supply terminal of the first operational amplifier.

A negative power supply terminal of the second operational amplifier may be connected to the ground.

A node between the first resistor and the second resistor may be connected to a non-inverting input of the first operational amplifier, and a node between the second resistor and the third resistor may be connected to a non-inverting input of the second operational amplifier.

An inverting input of the first operational amplifier may be connected to a source of the first transistor and a drain of the second transistor.

An inverting input of the second operational amplifier may be connected to a source of the second transistor and a drain of the third transistor.

The power amplifier may further include a third operational amplifier. An output terminal of the third operational amplifier may be connected to the gate of the third transistor.

The power amplifier may further include a mirror transistor. The output terminal of the third operational amplifier may be connected between a gate of the mirror transistor and the gate of the third transistor.

The electronic device according to various embodiments may be one of various types of electronic devices. The electronic devices may include, for example, a portable communication device (e.g., a smartphone), a computer device, a portable multimedia device, a portable medical device, a camera, a wearable device, or a home appliance. According to an embodiment of the disclosure, the electronic devices are not limited to those described above.

It should be appreciated that various embodiments of the disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B”, “at least one of A and B”, “at least one of A or B”, “A, B, or C”, “at least one of A, B, and C”, and “at least one of A, B, or C”, may include any one of, or all possible combinations of the items enumerated together in a corresponding one of the phrases. As used herein, such terms as “1st” and “2nd”, or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with”, “coupled to”, “connected with”, or “connected to” another element (e.g., a second element), it means that the element may be coupled with the other element directly (e.g., wiredly), wirelessly, or via a third element.

As used in connection with various embodiments of the disclosure, the term “module” may include a unit implemented in hardware, software, or firmware, and may interchangeably be used with other terms, for example, logic, logic block, part, or circuitry. A module may be a single integral component, or a minimum unit or part thereof, adapted to perform one or more functions. For example, according to an embodiment, the module may be implemented in a form of an application-specific integrated circuit (ASIC).

Various embodiments as set forth herein may be implemented as software (e.g., the program 140) including one or more instructions that are stored in a storage medium (e.g., internal memory 136 or external memory 138) that is readable by a machine (e.g., the electronic device 101). For example, a processor (e.g., the processor 120) of the machine (e.g., the electronic device 101) may invoke at least one of the one or more instructions stored in the storage medium, and execute it, with or without using one or more other components under the control of the processor. This allows the machine to be operated to perform at least one function according to the at least one instruction invoked. The one or more instructions may include a code generated by a complier or a code executable by an interpreter. The machine-readable storage medium may be provided in the form of a non-transitory storage medium. Wherein, the term “non-transitory” simply means that the storage medium is a tangible device, and does not include a signal (e.g., an electromagnetic wave), but this term does not differentiate between where data is semi-permanently stored in the storage medium and where the data is temporarily stored in the storage medium.

According to an embodiment, a method according to various embodiments of the disclosure may be included and provided in a computer program product. The computer program product may be traded as a product between a seller and a buyer. The computer program product may be distributed in the form of a machine-readable storage medium (e.g., compact disc read only memory (CD-ROM)), or be distributed (e.g., downloaded or uploaded) online via an application store (e.g., PlayStoreTM), or between two user devices (e.g., smart phones) directly. If distributed online, at least part of the computer program product may be temporarily generated or at least temporarily stored in the machine-readable storage medium, such as memory of the manufacturer's server, a server of the application store, or a relay server.

According to various embodiments, each component (e.g., a module or a program) of the above-described components may include a single entity or multiple entities, and some of the multiple entities may be separately disposed in different components. According to various embodiments, one or more of the above-described components may be omitted, or one or more other components may be added. Alternatively or additionally, a plurality of components (e.g., modules or programs) may be integrated into a single component. In such a case, according to various embodiments, the integrated component may still perform one or more functions of each of the plurality of components in the same or similar manner as they are performed by a corresponding one of the plurality of components before the integration. According to various embodiments, operations performed by the module, the program, or another component may be carried out sequentially, in parallel, repeatedly, or heuristically, or one or more of the operations may be executed in a different order or omitted, or one or more other operations may be added.

What is claimed is:

1. A power amplifier comprising:
an amplifier circuit comprising a first transistor, a second transistor, and a third transistor connected in a stacked cascode structure between a power supply voltage and a ground; and
a bias circuit comprising a first operational amplifier configured to provide a first bias voltage to the first transistor, and a second operational amplifier configured to provide a second bias voltage to the second transistor,
wherein the first operational amplifier comprises a positive input terminal connected to a first reference voltage divided from the power supply voltage, a negative input terminal connected to a source node of the first transistor, an output terminal configured to provide the first bias voltage to a gate node of the first transistor, a positive power supply terminal connected to the power supply voltage, and a negative power supply terminal, and
wherein the second operational amplifier comprises a positive input terminal connected to a second reference voltage divided from the power supply voltage, a negative input terminal connected to a source node of the second transistor, an output terminal configured to provide the second bias voltage to a gate node of the second transistor, a positive power supply terminal connected to the negative power supply terminal of the first operational amplifier, and a negative power supply terminal connected to the ground.

2. The power amplifier of claim 1, further comprising a resistor ladder comprising a first resistor, a second resistor, and a third resistor connected in series between the power supply voltage and the ground,
wherein the positive input terminal of the first operational amplifier is connected to the resistor ladder between the first resistor and the second resistor, and the positive input terminal of the second operational amplifier is connected to the resistor ladder between the second resistor and the third resistor.

3. The power amplifier of claim 2, wherein at least one of the first resistor, the second resistor, or the third resistor is a variable resistor.

4. The power amplifier of claim 1, wherein an input radio frequency (RF) signal is received through a gate node of the third transistor, and
wherein an amplified output RF signal corresponding to the input RF signal is output through a drain node of the first transistor.

5. The power amplifier of claim 4, further comprising an inductor coil connected between the power supply voltage and the drain node of the first transistor.

6. The power amplifier of claim 1, wherein the amplifier circuit further comprises a fourth transistor connected to the first transistor in a stacked cascode structure, and
wherein the bias circuit further comprises a third operational amplifier configured to provide a bias voltage to the fourth transistor.

7. The power amplifier of claim 6, further comprising a voltage regulator configured to generate source voltages to be provided to the first operational amplifier and the second operational amplifier, based on the power supply voltage.

8. The power amplifier of claim 1, further comprising an analog bias circuit comprising a mirror transistor corresponding to the third transistor and a third operational amplifier configured to provide a third bias voltage to the mirror transistor,
wherein the third operational amplifier comprises a positive input terminal connected to an analog power supply voltage, a negative input terminal connected to the positive input terminal of the second operational amplifier, a positive power supply terminal connected to the analog power supply voltage, and a negative power supply terminal connected to the ground, and
wherein the mirror transistor comprises a gate node connected to the gate node of the third transistor, a drain node connected to the analog power supply voltage via a reference current source, and a source node connected to the ground.

9. The power amplifier of claim 1, wherein the first transistor, the second transistor, and the third transistor are complementary metal-oxide-semiconductor (MOS) (CMOS) transistors.

10. The power amplifier of claim 1, wherein the amplifier circuit is configured to be used in a transmission path of an RF communication circuit configured to support a millimeter wave (mmWave) frequency band.

11. A communication circuit including a transmission path, wherein the transmission path comprises one or more power amplifiers, and among the one or more power amplifiers, at least one power amplifier comprises:
an amplifier circuit comprising a first transistor, a second transistor, and a third transistor connected in a stacked cascode structure between a power supply voltage and a ground; and
a bias circuit comprising a first operational amplifier configured to provide a first bias voltage to the first transistor, and a second operational amplifier configured to provide a second bias voltage the second transistor,
wherein the first operational amplifier comprises a positive input terminal connected to a first reference voltage divided from the power supply voltage, a negative input terminal connected to a source node of the first transistor, an output terminal configured to provide the first bias voltage to a gate node of the first transistor, a positive power supply terminal connected to the power supply voltage, and a negative power supply terminal, and
wherein the second operational amplifier comprises a positive input terminal connected to a second reference voltage divided from the power supply voltage, a negative input terminal connected to a source node of the second transistor, an output terminal configured to provide the second bias voltage to a gate node of the second transistor, a positive power supply terminal connected to the negative power supply terminal of the first operational amplifier, and a negative power supply terminal connected to the ground.

12. The communication circuit of claim 11, wherein the at least one power amplifier further comprises a resistor ladder including a first resistor, a second resistor, and a third resistor connected in series between the power supply voltage and the ground, and
wherein the positive input terminal of the first operational amplifier is connected to the resistor ladder between the first resistor and the second resistor, and the positive input terminal of the second operational amplifier is connected to the resistor ladder between the second resistor and the third resistor.

13. The communication circuit of claim 12, wherein at least one of the first resistor, the second resistor, or the third resistor is a variable resistor.

14. The communication circuit of claim 11, wherein an input radio frequency (RF) signal is received through a gate node of the third transistor, and
wherein an amplified output RF signal corresponding to the input RF signal is output through a drain node of the first transistor.

15. The communication circuit of claim 14, wherein the amplifier circuit further comprises an inductor coil connected between the power supply voltage and the drain node of the first transistor.

16. The communication circuit of claim 11, wherein the amplifier circuit further comprises a fourth transistor connected to the first transistor in a stacked cascode structure, and
wherein the bias circuit further comprises a third operational amplifier configured to provide a bias voltage to the fourth transistor.

17. The communication circuit of claim 16, wherein the amplifier circuit further comprises a voltage regulator configured to generate source voltages to be provided to the first operational amplifier and the second operational amplifier, based on the power supply voltage.

18. The communication circuit of claim 11, wherein the amplifier circuit further comprises an analog bias circuit including a mirror transistor corresponding to the third transistor and a third operational amplifier configured to provide a third bias voltage to the mirror transistor,
wherein the third operational amplifier comprises a positive input terminal connected to an analog power supply voltage, a negative input terminal connected to the positive input terminal of the second operational amplifier, a positive power supply terminal connected to the analog power supply voltage, and a negative power supply terminal connected to the ground, and
wherein the mirror transistor comprises a gate node connected to the gate node of the third transistor, a drain node connected to the analog power supply voltage via a reference current source, and a source node connected to the ground.

19. The communication circuit of claim 11, wherein the first transistor, the second transistor, and the third transistor are complementary metal-oxide-semiconductor (MOS) (CMOS) transistors.

20. The communication circuit of claim 11, wherein the transmission path is configured to support a millimeter wave (mmWave) frequency band.
